(19) United States
(12) Patent Application Publication
(10) Pub. No.: US 2015/0237743 A1
(43) Pub. Date: Aug. 20, 2015

(54) DISPLAY APPARATUS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: DA-LONG SUN, Wuhan (CN); YU-GUI CHEN, Wuhan (CN); ZHI-JUN ZHANG, Wuhan (CN)

(21) Appl. No.: 14/524,762

(22) Filed: Oct. 27, 2014

(30) Foreign Application Priority Data
Feb. 17, 2014 (CN) 2014100527749

(51) Int. Cl. H05K 5/00; H05K 5/06

(52) U.S. Cl. CPC H05K 5/0017; H05K 5/06

(57) ABSTRACT

A display apparatus includes a base, a screen, and a seal member. The base includes a mounting frame, and the mounting frame has a plurality of slanted surfaces. The screen includes a display panel and a plurality of side surfaces coupled to the display panel. The seal member is surrounded the display panel and attached to the plurality of side surfaces. The seal member is sandwiched between the screen and the mounting frame, and the plurality of slanted surfaces resists the seal member, to seal gaps between the screen and the mounting frame.

### CROSS-REFERENCE TO RELATED APPLICATIONS

This application claims priority to Chinese Patent Application No. 201410052774.9 filed on Feb. 17, 2014 in the China Intellectual Property Office, the contents of which are incorporated by reference herein.

### FIELD

The subject matter herein generally relates to a display apparatus for an electronic device.

### BACKGROUND

Displays are usually used to in electronic devices, such as tablet computers, All-In-ones, and so on. The display is always installed on a panel so that a slit will exist between the display and the panel.

### BRIEF DESCRIPTION OF THE DRAWINGS

Implementations of the present technology will now be described, by way of example only, with reference to the attached figures, wherein:

FIG. 1 is an exploded, isometric view of an embodiment of a display apparatus, and the display apparatus comprises a base, a display assembly and two resisting members.

FIG. 2 is similar to FIG. 1, but viewed from a different angle.

FIG. 3 is an enlarged view of circled portion III of FIG. 1.

FIG. 4 is isometric view of the resisting member of FIG. 1.

FIG. 5 is an assembled view of the display apparatus of FIG. 1.

FIG. 6 is a cross sectional view of taken along a line VI-VI of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

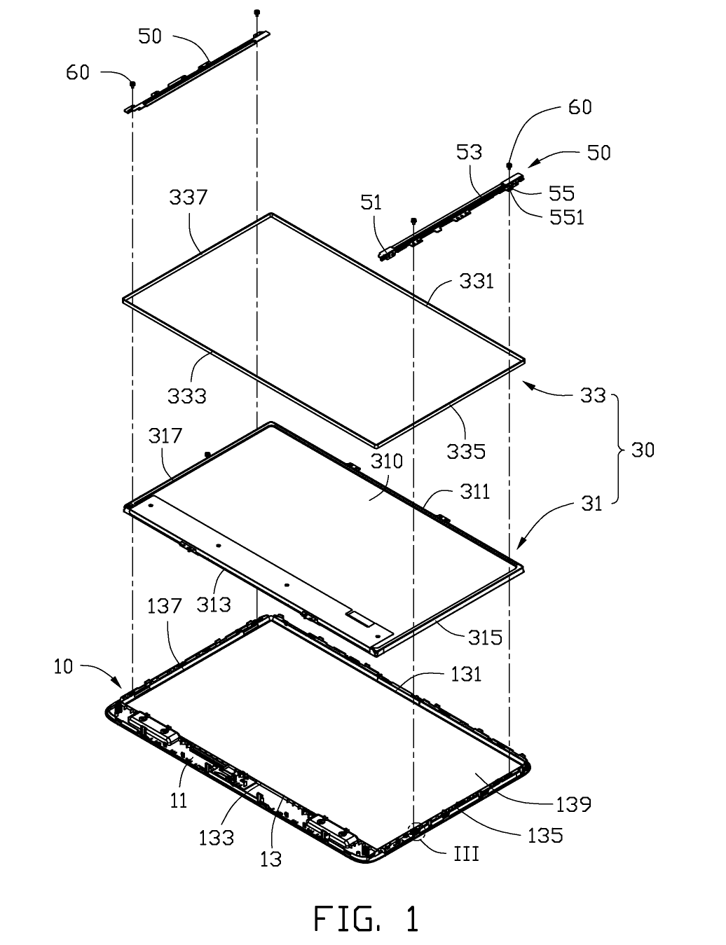

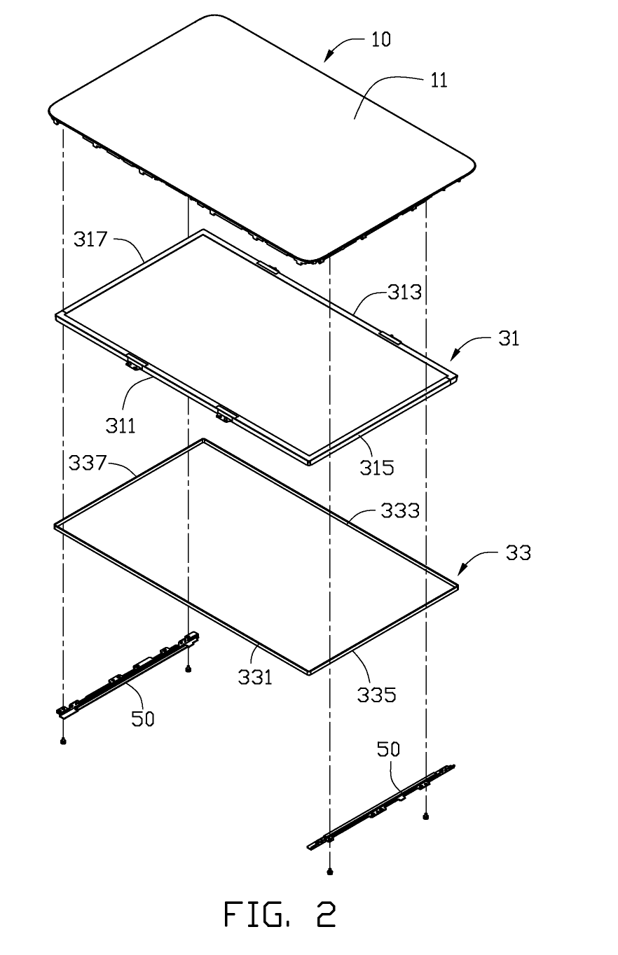

FIGS. 1 and 2 illustrate a display apparatus in accordance with an embodiment. The display apparatus can include a base 10, a display assembly 30, and two resisting members 50. The two resisting members 50 are used to secure the display assembly 30 to the base 10.

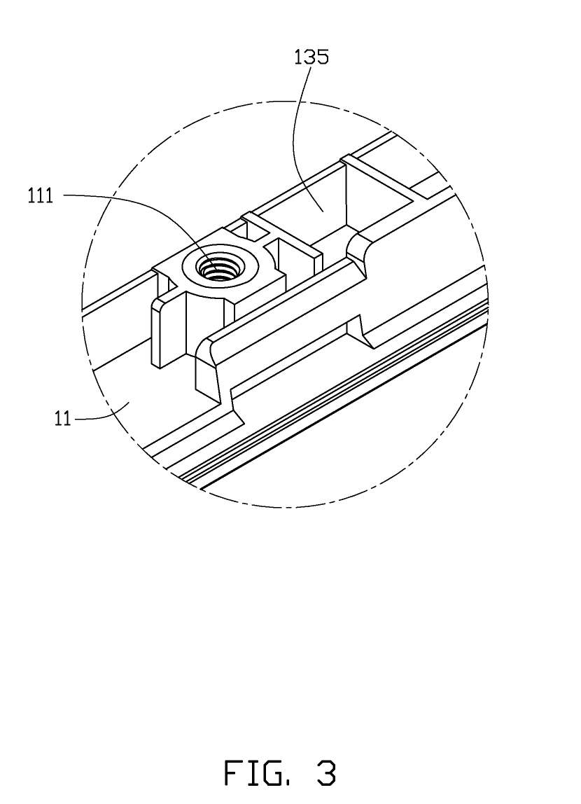

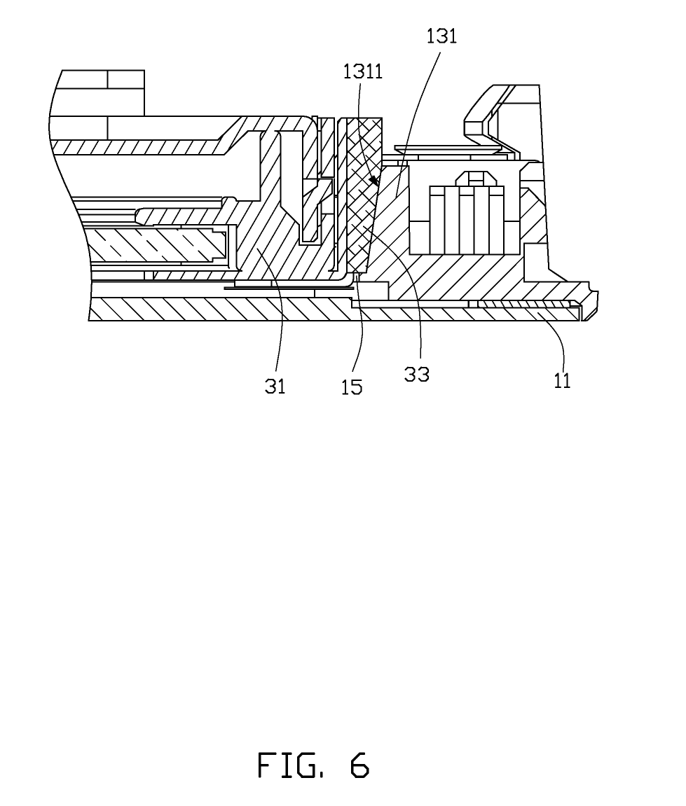

The base 10 can include a bottom plate 11 and a mounting frame 13. The mounting frame 13 can be integrated with the bottom plate 11 and can include a first sidewall 131, a second sidewall 133, a third sidewall 135, and a fourth sidewall 137. The first sidewall 131, the second sidewall 133, the third sidewall 135, and the fourth sidewall 137 cooperatively define a receiving space 139 for accommodating the display assembly 30. Each of the first sidewall 131, the second sidewall 133, the third sidewall 135, and the fourth sidewall 137 has a slanted surface 1311 (shown in FIG. 6). Referring to FIG. 3, the bottom plate 11 defines two thread holes 111 corresponding to each resisting member.

The display assembly 30 can include a screen 31, and a seal member 33. The screen 31 may be a liquid crystal display (LCD). The screen 31 can include a display panel 310, a first side surface 311, a second side surface 313, a third side surface 315, and a fourth side surface 317. The first side surface 311, the second side surface 313, the third side surface 315, and the fourth side surface 317 are substantially perpendicularly coupled to the display panel 310.

The seal member 33 can include a first seal piece 331, a second seal piece 333, a third seal piece 335, and a fourth seal piece 337. The first seal piece 331, the second seal piece 333, the third seal piece 335, and the fourth seal piece 337 are coupled to end to end. The lengths of the first seal piece 331 and the second seal piece 333 are substantially equal to the length of the screen 31. The lengths of the third seal piece 335 and the fourth seal piece 337 are substantially equal to the width of the screen 31. The widths of the first seal piece 331, the second seal piece 333, the third seal piece 335, and the fourth seal piece 337 are substantially equal to the thickness of the screen 31. In at least one embodiment, the seal member 33 is made with foam.

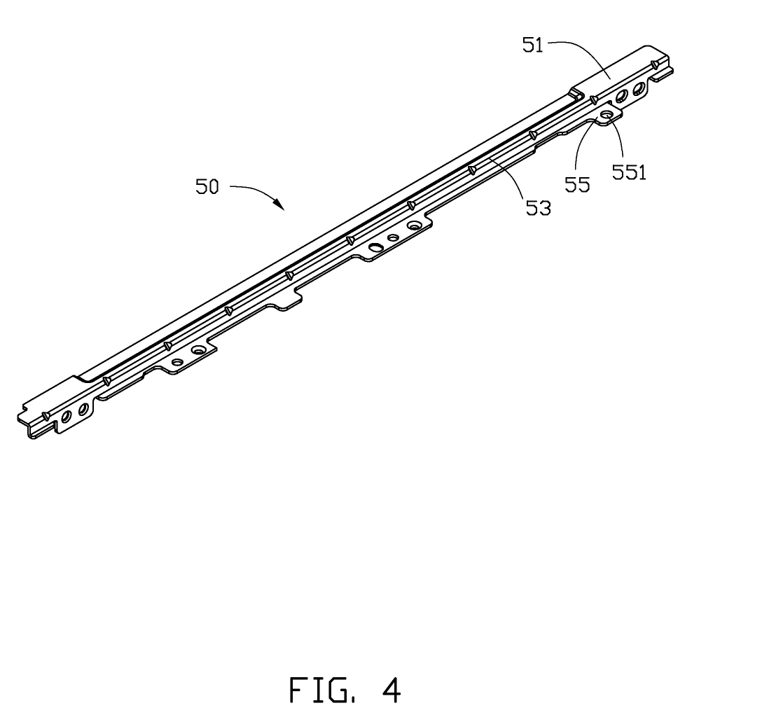

FIG. 4 shows that each resisting member 50 can include a resisting piece 51 and a flange 53. The flange 53 extends from one edge of the resisting piece 51. Two fixing tabs 55 extend from a bottom edge of the flange 53. Each of the two fixing tabs 55 defines a fixing hole 551.

FIGS. 1, 5 and 6 illustrate that in assembly, the seal member 33 is pasted on the screen 31, and the display assembly 30 is received in the receiving space 139. The first seal piece 331 is sandwiched between the first side surface 311 and the first sidewall 131, the second seal piece 333 is sandwiched between the second side surface 313 and the second sidewall 133, the third seal piece 335 is sandwiched between the third side surface 315 and the third sidewall 135, and the fourth seal piece 337 is sandwiched between fourth side surface 317 and the fourth sidewall 137. The slanted surface 1311 resists the seal member 33, and the seal member 33 is deformable sandwiched between the mounting frame 13 and the screen 31.

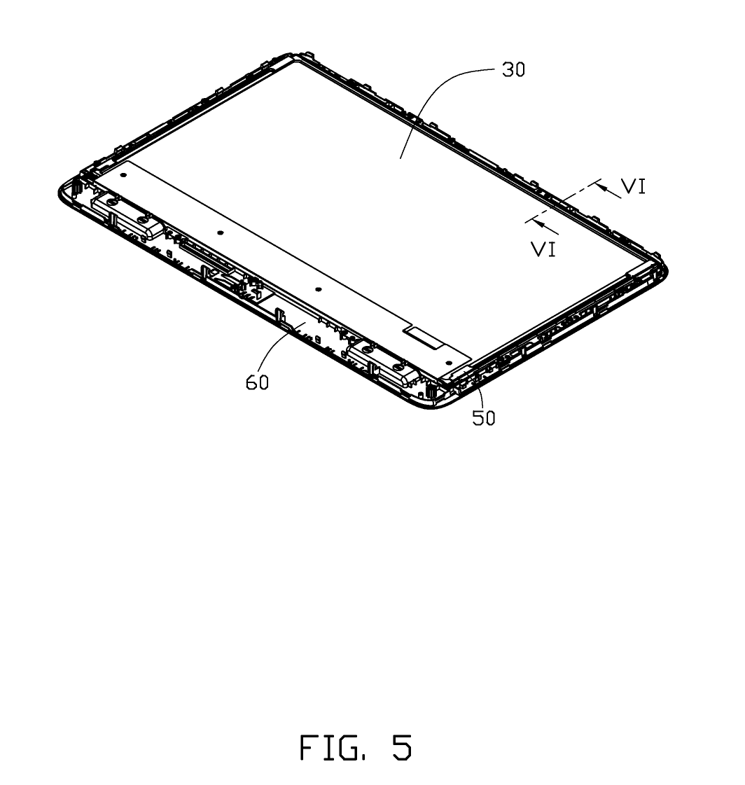

FIGS. 1 and 5 illustrate that the two resisting members 50 are placed on the bottom plate 11 and located on opposite sides of the screen 31. Each fixing hole 551 is aligned with each thread hole 111. A fastener 60 passes through the fixing hole 551 to be locked into the thread hole 111. The resisting piece 51 abuts the display assembly 30, to prevent the display assembly 30 from disengaging from the receiving space 139.

The embodiments shown and described above are only examples. Many details are often found in the art such as the other features of a display apparatus. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A display apparatus comprising:
a base comprising a mounting frame, the mounting frame having a plurality of slanted surfaces;
a display assembly comprising a display panel and a plurality of side surfaces coupled to the display panel; and
a seal member at least partially surrounding the display panel and attached to the plurality of side surfaces,
wherein the seal member is situated between a screen and the mounting frame, the plurality of slanted surfaces abutting against the seal member to seal gaps between the screen and the mounting frame.

2. The display apparatus of claim 1, wherein the seal member comprises a first seal piece, a second seal piece, a third seal piece, and a fourth seal piece, the lengths of the first seal piece and the second seal piece are substantially equal to the length of the screen, and the lengths of the third seal piece and the fourth seal piece are substantially equal to the width of the screen.

3. The display apparatus of claim 2, wherein the widths of the first seal piece, the second seal piece, the third seal piece, and the fourth seal piece are substantially equal to the thickness of the screen.

4. The display apparatus of claim 2, wherein the mounting frame comprises a first sidewall, a second sidewall, a third sidewall, and a fourth sidewall, the plurality of side surfaces comprises a first side surface, a second surface, a third surface, and a fourth surface, the first seal piece is positioned between the first side surface and the first sidewall, the second seal piece is positioned between the second sidewall and the second surface, the third seal piece is positioned between the third sidewall and the third surface, and the fourth seal piece is positioned between the fourth sidewall and the fourth surface.

5. The display apparatus of claim 4, wherein the width of the first sidewall and the first surface is slightly less than the thickness of the firs seal piece, the width of the second sidewall and the second surface is slightly less than the thickness of the second seal piece, the width of the third sidewall and the third surface is slightly less than the thickness of the third seal piece, and the width of the fourth sidewall and the fourth surface is slightly less than the thickness of the fourth seal piece.

6. The display apparatus of claim 4, wherein each of the first sidewall, the second sidewall, the third sidewall, and the fourth sidewall have the plurality of slanted surfaces, and the plurality of slanted surfaces is slanted towards the seal member.

7. The display apparatus of claim 1, wherein the seal is made with foam.

8. A display apparatus comprising:
a base;
a screen comprising a display panel and a plurality of side surfaces coupled to the display panel; and
a seal member at least partially surrounding the display panel and attached to the plurality of side surfaces,
wherein the seal member is deformably situated between the screen and the base to seal gaps between the screen and the base.

9. The display apparatus of claim 8, wherein the seal member comprises a first seal piece, a second seal piece, a third seal piece, and a fourth seal piece, the lengths of the first seal piece and the second seal piece are substantially equal to the length of the screen, and the lengths of the third seal piece and the fourth seal piece are substantially equal to the width of the screen.

10. The display apparatus of claim 9, wherein the widths of the first seal piece, the second seal piece, the third seal piece, and the fourth seal piece are substantially equal to the thickness of the screen.

11. The display apparatus of claim 9, wherein the base further comprises a mounting frame, and the mounting frame has a plurality of slanted surfaces, the seal member is sandwiched between the plurality of side surface and the mounting frame, and the plurality of slanted surfaces resists the seal member.

12. The display apparatus of claim 11, wherein the mounting frame comprises a first sidewall, a second sidewall, a third sidewall, and a fourth sidewall, the plurality of side surfaces comprises a first side surface, a second surface, a third surface, and a fourth surface, the first seal piece is positioned between the first side surface and the first sidewall, the second seal piece is positioned between the second sidewall and the second surface, the third seal piece is positioned between the third sidewall and the third surface, and the fourth seal piece is positioned between the fourth sidewall and the fourth surface.

13. The display apparatus of claim 12, wherein the width of the first sidewall and the first surface is slightly less than the thickness of the firs seal piece, the width of the second sidewall and the second surface is slightly less than the thickness of the second seal piece, the width of the third sidewall and the third surface is slightly less than the thickness of the third seal piece, and the width of the fourth sidewall and the fourth surface is slightly less than the thickness of the fourth seal piece.

14. The display apparatus of claim 13, wherein each of the first sidewall, the second sidewall, the third sidewall, and the fourth sidewall have the plurality of slanted surfaces, and the plurality of slanted surfaces is slanted towards the seal member.

15. The display apparatus of claim 11, further comprises two resisting members, wherein the base comprises a bottom plate integrated with the mounting frame, and the two resisting members are secured to the bottom plate and press the screen.

16. The display apparatus of claim 8, wherein the seal is made with foam.

17. A display assembly comprising:
a screen comprising a display panel and a plurality of side surfaces coupled to the display panel; and
a seal member surrounded the display panel and attached to the plurality of side surface.

18. The display apparatus of claim 17, wherein the seal member comprises a first seal piece, a second seal piece, a third seal piece, and a fourth seal piece, the lengths of the first seal piece and the second seal piece are substantially equal to the length of the screen, and the lengths of the third seal piece and the fourth seal piece are substantially equal to the width of the screen.

19. The display apparatus of claim 18, wherein the widths of the first seal piece, the second seal piece, the third seal piece, and the fourth seal piece are substantially equal to the thickness of the screen.
